(19) United States
(12) Patent Application Publication
(10) Pub. No.: US 2021/0204437 A1
(43) Pub. Date: Jul. 1, 2021

(54) CHASSIS INTERNAL CONNECTION STRUCTURE FOR SERVER

(71) Applicant: Super Micro Computer Inc., San Jose, CA (US)

(72) Inventors: Charles Jian-Hou LIANG, San Jose, CA (US); Ben-Koon LIN, San Jose, CA (US)

(21) Appl. No.: 16/728,488

(22) Filed: Dec. 27, 2019

(51) Int. Cl. H05K 7/14; H05K 1/18; H05K 1/14

(52) U.S. Cl. CPC H05K 7/1487; H05K 1/181; H05K 2201/10159; H05K 2201/10356; H05K 2201/10189; H05K 1/141

(57) ABSTRACT

A chassis internal connection structure for a server includes a casing having an accommodating space. A motherboard is arranged in a computation zone and includes a first central processor and a first connection port. A plurality of data processing units is arranged in a data link zone. A bus assembly includes a flexible bus cable and connectors. The connectors comprise a motherboard connector singularly arranged on one end of the flexible bus cable and data processing unit connectors arranged on another end thereof. The motherboard connector is electrically connected to the first connection port, and the data processing unit connectors are correspondingly connected to the data processing units respectively. The data processing units are connected to the first central processor via the bus assembly. Accordingly, the chassis internal connection structure is simplified.

### BACKGROUND OF THE INVENTION

### Field of the Invention

The technical field relates to a server system, in particular, to a chassis internal connection structure for a server.

### Description of Related Art

Presently, a server system includes a plurality of chassis installed inside the cabinet, and each chassis is installed with electronic devices of an independent motherboard, a backboard, a plurality of data processing units and power supply etc. in order to facilitate the maintenance and expansion of each chassis.

Furthermore, the internal of chassis of conventional server systems are mostly installed with a computation zone and a data link zone. The computation zone is installed with a motherboard, and the data link zone is installed with a backboard and a plurality of data processing units. In addition, the backboard is connected to the motherboard via an adapter card, and the data processing units are connected to the backboard via a plurality of wires such that these data processing units are able to form electrical connection with the motherboard, thereby achieving signal or power transmission. Nevertheless, since the size of the aforementioned backboard is large and occupies the internal space of the chassis, it hinders the installation of other mechanical parts and electronic elements, and it also causes the increase of the overall cost. Consequently, there is a need for improvement of such drawback.

In view of above, the inventor seeks to overcome the aforementioned drawback associated with the currently existing technology after years of research and development along with the utilization of academic theories, which is also the objective of the development of the present invention.

### SUMMARY OF THE INVENTION

An objective of the present invention is to provide a chassis internal connection structure for a server capable of simplifying the chassis internal connection structure and reducing the overall cost.

To achieve the aforementioned objective, the present invention provides a chassis internal connection structure for a server, comprising a casing, a motherboard, a plurality of data processing units and a bus assembly. The casing includes an accommodating space comprising a computation zone and a data link zone. The motherboard is installed in the computation zone and having a first central processor arranged thereon and a first connection port electrically connected to the first central processor. The plurality of data processing units is arranged in the data link zone. The bus assembly comprises a flexible bus cable and a plurality of connector connected to the flexible bus cable. The connectors comprise a motherboard connector singularly arranged on one end of the flexible bus cable and a plurality of data processing unit connectors arranged on another end of the flexible bus cable. The motherboard connector is electrically connected to the first connection port. The data processing unit connectors are correspondingly connected to the data processing units respectively. Each one of the data processing units is connected to the first central processor via the bus assembly.

Another objective of the present invention is to provide a chassis internal connection structure for a server, wherein the chassis internal connection structure further comprises a PCI-e interface card, a PCI-e bus assembly and a function expansion slot. One end of the PCI-e bus assembly is inserted into the function expansion slot and another end thereof is connected to the busy assembly connection portion, thereby achieving the objective of function expansion.

Still another objective of the present invention is to provide a chassis internal connection structure for a server, further comprising a circuit bus assembly. The circuit bus assembly comprises a plurality of PCI-e circuits arranged thereon and a plurality of circuit connectors, and it is directly installed on the PCI-e interface card, thereby achieving the objective of fast, large volume or instant transmission.

Still another objective of the present invention is to provide a chassis internal connection structure for a server, further comprising a PCI-e adapter card and an adaptor bus assembly. One end of the adapter bus assembly is inserted into the PCI-e adapter card and another end thereof is connected to the motherboard, thereby achieving the objective of function expansion.

In comparison to the prior art, in the chassis internal connection structure of the present invention, the data processing units and the motherboard are not using the traditional backboard element for electrical connection. On the contrary, the electrical connection between the data processing units of the present invention and the motherboard is achieved directly via the bus assembly. In addition, the bus assembly comprises a flexible bus cable and connectors, wherein the connectors comprise a motherboard connector singularly arranged on one end of the flexible bus cable and a plurality of data processing unit connectors arranged on another end of the flexible bus cable. Furthermore, the motherboard connector is electrically connected to the first connection port, and the data processing unit connectors are correspondingly connected to the data processing units respectively. Each one of the data processing units is connected to the first central processor via the bus assembly. Accordingly, the chassis internal connection structure is simplified and the overall cost is reduced, such that the practicability of the present invention is enhanced.

### BRIEF DESCRIPTION OF DRAWING

FIG. 1 is a top view of the chassis internal connection structure for a server of the present invention;

FIG. 2 is a perspective appearance view of the chassis internal connection structure for a server of the present invention;

FIG. 3 is an assembly view of the chassis internal connection structure for a server according to another embodiment of the present invention; and

FIG. 4 is a perspective appearance view of the chassis internal connection structure for a server according to another embodiment of the present invention.

### DETAILED DESCRIPTION OF THE INVENTION

The following provides a detailed technical content of the present invention along with the accompanied drawings. However, the accompanied drawings are provided for reference and illustrative purpose only such that they shall not be used to limit the scope of the present invention.

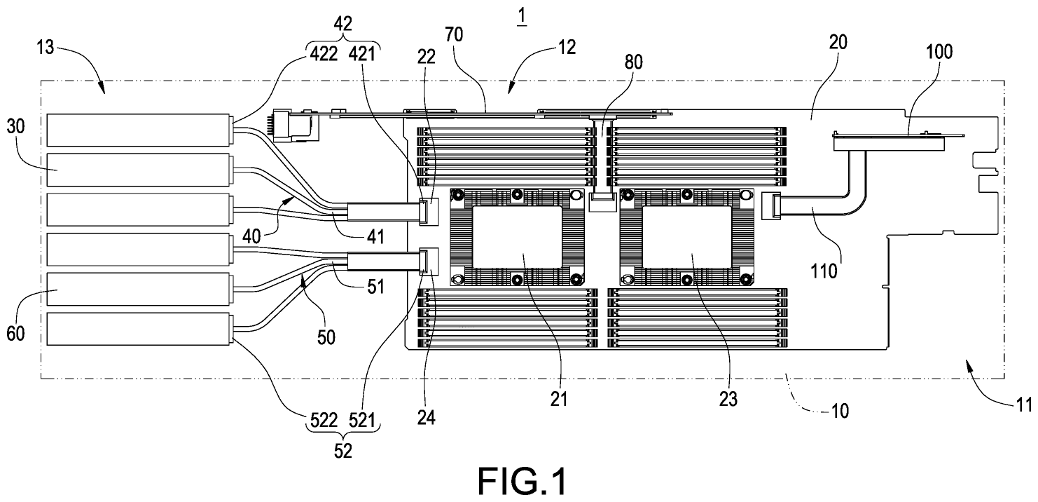

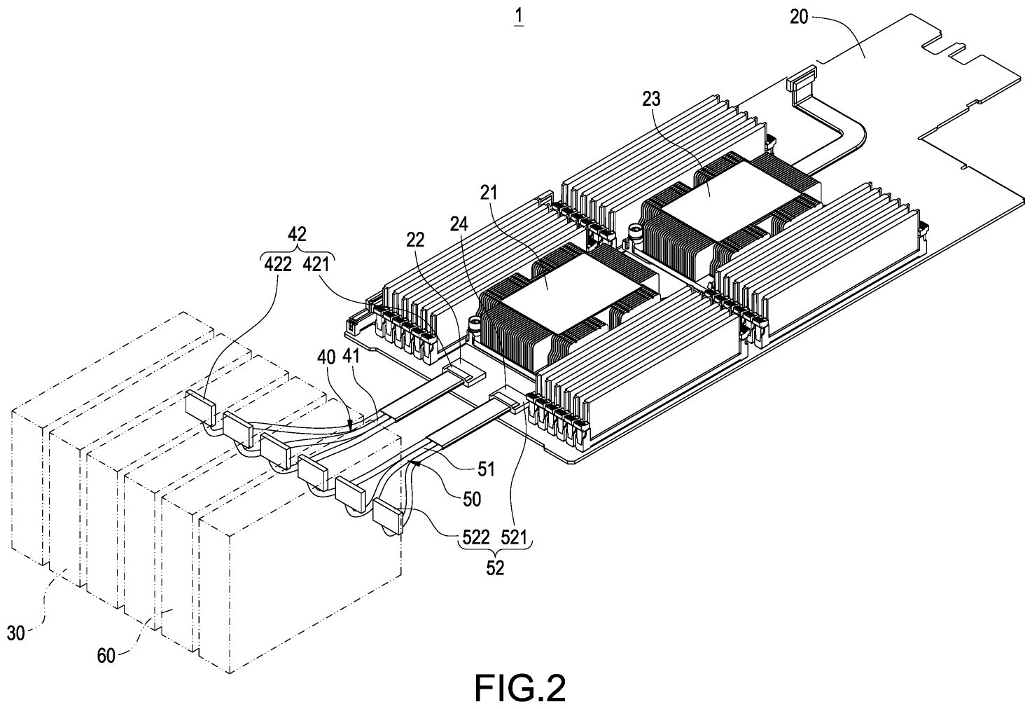

Please refer to FIG. 1 and FIG. 2, showing the top view and perspective appearance view of a chassis internal connection structure for a server of the present invention. The present invention provides a chassis internal connection structure 1 for a server, comprising a casing 10, a motherboard 20, a plurality of data processing units 30 and a bus assembly 40. The motherboard 20 and the plurality of data processing units 30 are arranged inside the casing 10, and the plurality of data processing units 30 achieve electrical connection via the bus assembly 40. For further details, please refer to the following description of the chassis internal connection structure 1.

The casing 10 includes an accommodating space 11, and the accommodating space 11 comprises a computation zone 12 and a data link zone 13. In addition, the motherboard 20 is installed in the computation zone 12, and the plurality of data processing units 30 is arranged in the data link zone 13. In addition, the motherboard 20 includes a first central processor 21 arranged thereon and a first connection port 22 electrically connected to the first central processor 21.

Furthermore, the bus assembly 40 comprises a flexible bus cable 41 and a plurality of connectors 42 connected to the flexible bus cable 41. The plurality of connectors 42 comprises a motherboard connector 421 singularly arranged on one end of the flexible bus cable 41 and a plurality of data processing unit connectors 422 arranged on another end of the flexible bus cable 41. Moreover, the motherboard connector 421 is electrically connected to the first connection port 22. The plurality of data processing unit connectors 422 is correspondingly connected to the data processing units 30 respectively. Each one of the data processing units 30 is connected to the first central processor 21 via the bus assembly 40.

It shall be noted that in an exemplary embodiment, the data processing unit 30 can configured to be an Enterprise Datacenter Small Form Factor (EDSFF) or an Advance Input Output Module (AIOM). In addition, the Enterprise Datacenter Small Form Factor can be a data storage element, such as a Solid-State Drive (SSD) etc.

In addition, it shall also be noted that the flexible bus cable 41 includes a plurality of metal wires, signal wires and power wires (not shown in the drawings) embedded therein; however, the present invention is not limited to such configuration only in real practice.

In an exemplary embodiment of the present invention, the motherboard 20 includes a second central processor 23 and a second connection port 24 electrically connected to the second central processor 23. Preferably, the second central processor 23 is aligned linearly with the first central processor 21, and the second connection port 24 is arranged in parallel with the first connection port 22.

Accordingly, the chassis internal connection structure 1 further comprises a second bus assembly 50 and a plurality of second data processing units 60 arranged in the data link zone 13. One end of the second bus assembly 50 is electrically connected to the second connection port 24 and another end thereof is correspondingly connected to each one of the second data processing units 60 respectively. Each one of the second data processing units 60 is connected to the second central processor 23 via the second bus assembly 50.

To more specific, the second bus assembly 50 comprises a second flexible bus cable 51 and a plurality of second connectors 52 connected to the second flexible bus cable 51. The plurality of second connectors 52 comprises a second motherboard connector 521 singularly arranged on one end of the second flexible bus cable 51 and a plurality of data processing unit connectors 522 arranged on another end of the second flexible bus cable 51. The second motherboard connector 521 is electrically connected to the second connection port 24. The plurality of second data processing unit connectors 522 is correspondingly connected to the second data processing units 60 respectively.

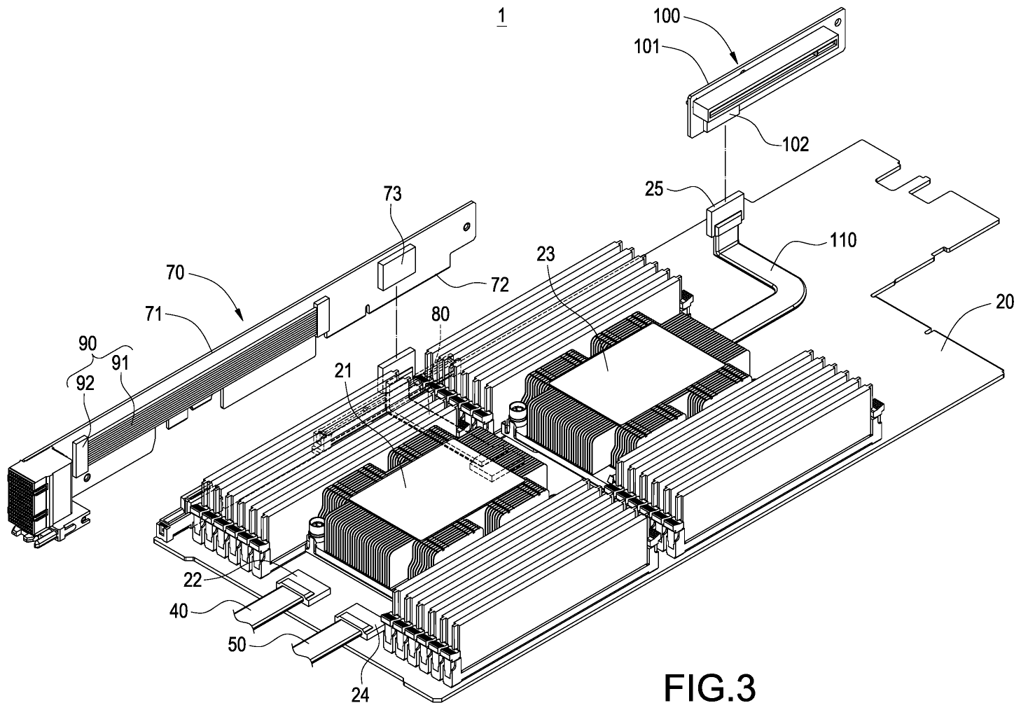

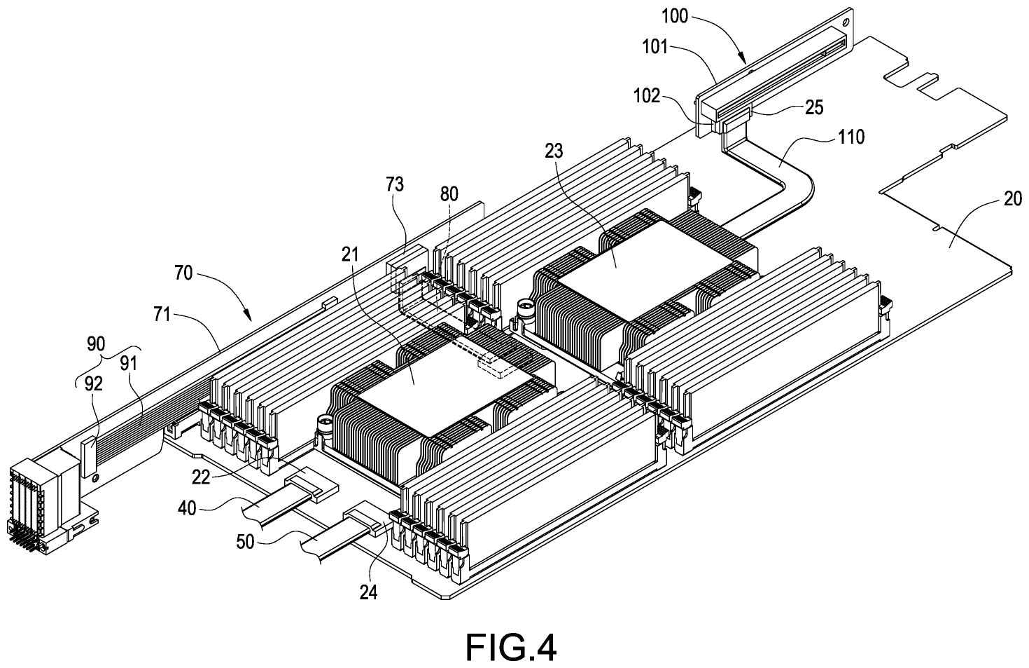

Please continue to refer to FIG. 3 and FIG. 4, showing an assembly view and a perspective appearance view of a chassis internal connection structure for a server according to another exemplary embodiment of the present invention. In an exemplary embodiment of the present invention, the chassis internal connection structure 1 further comprises a PCI-e interface card 70, a PCI-e bus assembly 80 and at least one function expansion slot 25. The PCI-e interface card 70 includes an interface card main body 71 and a gold finger connection portion 72 arranged on the interface card main body 71 and a bus assembly connection portion 73. In addition, the at least one function expansion slot 25 is arranged on the motherboard 20. One end of the PCI-e bus assembly 80 is inserted into the function expansion slot 25 and another end thereof is connected to the bus assembly connection portion 73.

It shall be noted that the connection method between the PCI-e interface card 70 and the gold finger connection portion 72 and the motherboard 20 is known, such that details thereof is omitted hereafter.

Furthermore, it shall be noted that in an exemplary embodiment of the present invention, the chassis internal connection structure 1 further comprises a circuit bus assembly 90. The circuit bus assembly 90 comprises a circuit flexible bus cable 91 having a plurality of PCI-e circuits (not shown in the drawings) arranged thereon and a plurality of circuit connectors 92 connected to the circuit flexible bus cable 91. Moreover, two ends of the plurality of circuit connectors 92 are electrically connected to the PCI-e interface card 70 respectively. Accordingly, when the user requires larger transmission volume or faster transmission speed, the wire layout originally arranged on the PCI-e interface card 70 can be changed to be directly arranged on the circuit bus assembly 90 in order to achieve the demand for fast and instant transmission.

In addition, when the motherboard 20 has sufficient space, the chassis internal connection structure 1 can further comprise a PCI-e adapter card 100 and an adaptor bus assembly 110. Preferably, the PCI-e adapter card 100 and the PCI-e interface card 70 are spaced apart from each other and are arranged on one side edge of the motherboard 20.

In an exemplary embodiment of the present invention, the PCI-e adapter card 100 includes an adapter card main body 101 and an adapter slot 102 arranged on the adapter main body 101. Furthermore, one end of the adapter bus assembly 110 is inserted into the adapter slot 102 and another end thereof is connected to the motherboard 20. Accordingly, the present invention is able to achieve the objective of function expansion through the configuration of the PCI-e adapter card 100 and the adapter bus assembly 110.

The above describes the preferable and feasible exemplary embodiments of the present invention for illustrative purposes only, which shall not be treated as limitations of the scope of the present invention. Any equivalent changes and modifications made in accordance with the scope of the claims of the present invention shall be considered to be within the scope of the claim of the present invention.

What is claimed is:

1. A chassis internal connection structure for a server, comprising:
a casing having an accommodating space comprising a computation zone and a data link zone;
a motherboard installed in the computation zone and having a first central processor arranged thereon and a first connection port electrically connected to the first central processor;
a plurality of data processing units arranged in the data link zone; and
a bus assembly comprising a flexible bus cable and a plurality of connectors connected to the flexible bus cable; the plurality of connectors comprising a motherboard connector singularly arranged on one end of the flexible bus cable and a plurality of data processing unit connectors arranged on another end of the flexible bus cable; the motherboard connector electrically connected to the first connection port; the plurality of data processing unit connectors correspondingly connected to the data processing units respectively; each one of the data processing units connected to the first central processor via the bus assembly.

2. The chassis internal connection structure for a server according to claim 1, wherein the flexible bus cable includes a plurality of metal wires, signal wires and power wires embedded therein.

3. The chassis internal connection structure for a server according to claim 1, wherein the motherboard includes a second central processor and a second connection port electrically connected to the second central processor; the second central processor is aligned linearly with the first central processor, and the second connection port is arranged in parallel with the first connection port.

4. The chassis internal connection structure for a server according to claim 3, further comprising a second bus assembly and a plurality of second data processing units arranged in the data link zone; wherein one end of the second bus assembly is electrically connected to the second connection port and another end thereof is correspondingly connected to each one of the second data processing units respectively; each one of the second data processing units is connected to the second central processor via the second bus assembly.

5. The chassis internal connection structure for a server according to claim 4, wherein the second bus assembly comprises a second flexible bus cable and a plurality of second connectors connected to the second flexible bus cable; the plurality of second connectors comprises a second motherboard connector singularly arranged on one end of the second flexible bus cable and a plurality of data processing unit connectors arranged on another end of the second flexible bus cable; the second motherboard connector is electrically connected to the second connection port; the plurality of second data processing unit connectors is correspondingly connected to the second data processing units respectively.

6. The chassis internal connection structure for a server according to claim 1, further comprising a PCI-e interface card, a PCI-e bus assembly and at least one function expansion slot; wherein the PCI-e interface card includes an interface card main body and a gold finger connection portion arranged on the interface card main body and a bus assembly connection portion; the at least one function expansion slot is arranged on the motherboard; one end of the PCI-e bus assembly is inserted into the at least one function expansion slot and another end thereof is connected to the bus assembly connection portion.

7. The chassis internal connection structure for a server according to claim 6, further comprising a circuit bus assembly; wherein the circuit bus assembly comprises a circuit flexible bus cable having a plurality of PCI-e circuits arranged thereon and a plurality of circuit connectors connected to the circuit flexible bus cable; two ends of the plurality of circuit connectors are electrically connected to the PCI-e interface card respectively.

8. The chassis internal connection structure for a server according to claim 6, further comprising a PCI-e adapter card and an adaptor bus assembly; wherein the PCI-e adapter card includes an adapter card main body and an adapter slot arranged on the adapter main body; one end of the adapter bus assembly is inserted into the adapter slot and another end thereof is connected to the motherboard.

9. The chassis internal connection structure for a server according to claim 8, wherein the PCI-e adapter card and the PCI-e interface card are spaced apart from each other and arranged on one side edge of the motherboard.

10. The chassis internal connection structure for a server according to claim 1, wherein the data processing unit is an enterprise datacenter small form factor or an advance input output module

11. The chassis internal connection structure for a server according to claim 10, wherein the enterprise datacenter small form factor is a solid-state drive.
